(19) United States
(12) Patent Application Publication
(10) Pub. No.: US 2016/0284898 A1
(43) Pub. Date: Sep. 29, 2016

(54) SOLAR CELL

(71) Applicant: NEO SOLAR POWER CORP., Hsinchu City (TW)

(72) Inventors: Shan-Chuang PEI, Hsinchu City (TW); Shao-Wei HUANG, Hsinchu City (TW); Je-Wei LIN, Hsinchu City (TW); Wei-Chih HSU, Hsinchu City (TW)

(73) Assignee: NEO SOLAR POWER CORP., Hsinchu City (TW)

(21) Appl. No.: 15/078,625

(22) Filed: Mar. 23, 2016

(30) Foreign Application Priority Data
Mar. 27, 2015 (TW) 104110144

(51) Int. Cl. H01L 31/0224; H01L 31/0216

(52) U.S. Cl. CPC H01L 31/022441; H01L 31/02168; H01L 31/02167

(57) ABSTRACT

A solar cell, including a semiconductor substrate, a first-type dopant layer and a second-type dopant layer that are respectively disposed on two surfaces of the semiconductor substrate, a first passivation layer formed on the first-type dopant layer, a first anti-reflection layer formed on the first passivation layer, a plurality of back electrodes passing through the first anti-reflection layer and the first passivation layer, a second passivation layer formed on the second-type dopant layer, a second anti-reflection layer formed on the second passivation layer, and a plurality of front surface electrodes passing through the second anti-reflection layer and the second passivation layer. Widths of the back electrodes formed on a central area are smaller than those of the back electrodes formed on side areas.

### CROSS-REFERENCES TO RELATED APPLICATIONS

This non-provisional application claims priority under 35 U.S.C. §119(a) on Patent Application No. 104110144 filed in Taiwan, R.O.C. on Mar. 27, 2015, the entire contents of which are hereby incorporated by reference.

### BACKGROUND

1. Technical Field

The present invention relates to back electrode design of a solar cell.

2. Related Art

The solar cell is a green energy technology that most maturely develops and that is most widely applied at present, and in order to improve power generation efficiency of the solar cell and lower power generation costs, various solar cell structures are continuously developed. Solar cells may approximately be classified into three types such as a silicon-based solar cell, a compound semiconductor solar cell, and an organic solar cell, where a technology of the silicon-based solar cell is the most mature and also the most popular, and in particular, conversion efficiency of a monocrystalline silicon solar cell is the highest among all solar cells.

At present, there are up to more than ten types of crystalline silicon solar cells having high conversion efficiency, among which, roughly, Hetero-junction with Intrinsic Thin Layer (HIT) solar cells, interdigitated back contact (IBC) solar cells, bifacial solar cells, and Passivated Emitter Rear Locally Diffused (PERL) solar cells have a possibility of commercial scale mass production.

When a bifacial solar cell is manufactured or a PERL solar cell is manufactured, an anti-reflection layer and a passivation layer that are formed on a back surface must be etched through in a laser ablation manner, so as to expose a semiconductor layer located below the passivation layer, where through-holes obtained by means of laser ablation usually present an elongated strip shape and are spaced from each other at equal intervals. Subsequently, aluminum paste is scraped in a screen printing manner into the through-holes obtained by means of laser ablation, and then, it is only necessary to carry out an aluminum paste sintering procedure, so as to form a lattice-shaped back electrode on the back surface of the solar cell.

However, before the aluminum paste is printed, screen plate patterns must first be aligned with through-hole patterns obtained by means of laser ablation, but a certain alignment error exists in a screen printing machine, and in addition, after a screen plate is continuously used for a long term or used for many times, a situation of material fatigue would easily occur. A final result is causing misalignment between the back electrode and the through hole obtained by means of laser ablation, which leads to occurrence of a misalignment situation. The misalignment situation may be generalized into two types, which are rotational misalignment and translational misalignment, separately. Please refer to FIG. 1, which is a rotational misalignment schematic diagram (I). In this drawing, a back electrode 91 rotates by a degree relative to an etch hole 92 obtained by means of laser ablation, but the back electrode 91 can still entirely cover the etch hole 92 obtained by means of laser ablation. Please refer to FIG. 3, which is a translational misalignment schematic diagram (I). In this drawing, a back electrode 91 translates by a distance relative to an etch hole 92 obtained by means of laser ablation, but the back electrode 91 can still entirely cover the etch hole 92 obtained by means of laser ablation. When the misalignment situation is not seriously, that is, the back electrode 91 can still entirely cover the etch hole 92 obtained by means of laser ablation, existence of the misalignment in fact does not exert notable influence on conversion efficiency of the solar cell. Please further refer to FIG. 2 and FIG. 4, which are a rotational misalignment schematic diagram (II) and a translational misalignment schematic diagram (II) respectively. When a degree of the misalignment causes that the etch hole 92 obtained by means of laser ablation is not entirely covered by the back electrode 91, the conversion efficiency of the solar cell would obviously decrease. In the field of solar cells, even if the conversion efficiency only decreases by 0.1%, because a power generation amount of a solar power plant is measured in millions of watts, a total number of watts of generated power would obviously decrease, resulting in an increase of power generation costs per watt.

It is found in screen printing practices that the foregoing misalignment usually occurs in a back electrode formed on two side areas of a solar cell, more easily occurs as a distance to a central area increases, and relatively rarely occurs in a back electrode formed on the central area.

### SUMMARY

In view of the above, the present invention provides a solar cell, including a semiconductor substrate, doped with a first-type dopant and having a first surface and a second surface opposite to the first surface, where the first surface has a central area and at least two side areas, and the at least two side areas are respectively formed on two sides of the central area; a first dopant layer, formed on the first surface, where the first dopant layer is doped with the first-type dopant, a concentration of the first-type dopant of the first dopant layer is greater than a concentration of the first-type dopant of the semiconductor substrate; a first passivation layer, formed on the first dopant layer and having a plurality of first through-holes; a first anti-reflection layer, formed on the first passivation layer and having a plurality of second through-holes individually corresponding to the plurality of the first through-holes; a plurality of back surface fields, formed at the first dopant layer and individually corresponding to the plurality of first through-holes, where a concentration of the first-type dopant of the plurality of back surface fields is greater than the concentration of the first-type dopant of the first dopant layer; a plurality of back electrodes, arranged at intervals and being individually in electrical contact with the plurality of back surface fields through the plurality of second through-holes and the plurality of first through-holes, where widths of the plurality of back electrodes formed on the at least two side areas are greater than widths of the plurality of back electrodes formed on the central area; a second dopant layer, formed on the second surface, where the second dopant layer is doped with a second-type dopant; a second passivation layer, formed on the second dopant layer and having a plurality of third through-holes; a second anti-reflection layer, formed on the second passivation layer and having a plurality of fourth through-holes individually corresponding to the plurality of third through-holes; and a plurality of front surface electrodes, being individually in electrical contact with the second dopant layer through the third through-holes and the fourth through-holes.

One concept of the present invention is that the central area extends to edges of the semiconductor substrate along two sides parallel to a length direction of the back electrodes, the at least two side areas are respectively formed on two sides, of the central area, vertical to the length direction of the back electrodes, and a size of the central area is one tenth to one third of a size of the first surface.

One concept of the present invention is that the size of the central area is one tenth to one fifth of the size of the first surface.

One concept of the present invention is that the widths of the plurality of back electrodes formed on the central area fall within a range of 30 microns to 100 microns.

One concept of the present invention is that the widths of the plurality of back electrodes formed on the at least two side areas fall within a range of 40 microns to 250 microns.

One concept of the present invention is that the widths of the plurality of back electrodes formed on the central area fall within a range of 30 microns to 150 microns.

One concept of the present invention is that the widths of the plurality of back electrodes formed on the at least two side areas fall within a range of 40 microns to 250 microns.

One concept of the present invention is that the widths of the plurality of back electrodes formed on the central area are identical to each other.

One concept of the present invention is that the widths of the plurality of back electrodes formed on the at least two side areas are identical to each other.

One concept of the present invention is that the first surface has a central line parallel to a length direction of the back electrodes, the plurality of back electrodes is arranged at intervals in a direction vertical to the central line, and widths of the plurality of back electrodes increase as a distance to the central line increases.

### BRIEF DESCRIPTION OF THE DRAWINGS

The present invention will become more fully understood from the detailed description given herein below for illustration only, and thus are not limitative of the present invention, and wherein:

FIG. 1 is a rotational misalignment schematic diagram (I) in the prior art;

FIG. 2 is a rotational misalignment schematic diagram (II) in the prior art;

FIG. 3 is a translational misalignment schematic diagram (I) in the prior art;

FIG. 4 is a translational misalignment schematic diagram (II) in the prior art;

FIG. 5 is a schematic sectional diagram of a solar cell according to a first/second embodiment of the present invention;

FIG. 6 is a schematic diagram of a screen printing process according to the present invention;

FIG. 7 is a top view of a back surface of the solar cell according to the first/second embodiment of the present invention; and

FIG. 8 is a top view of a back surface according to a third embodiment of the present invention.

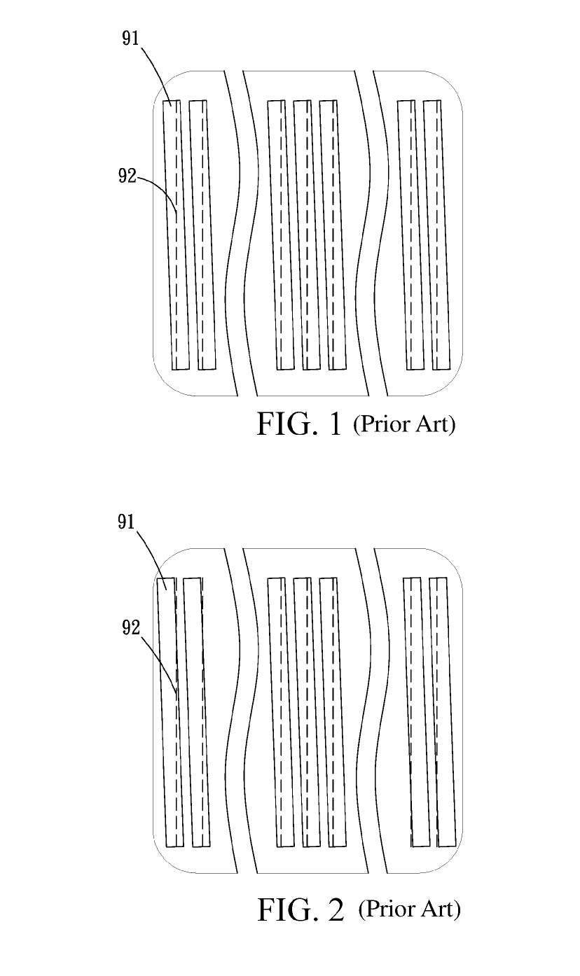

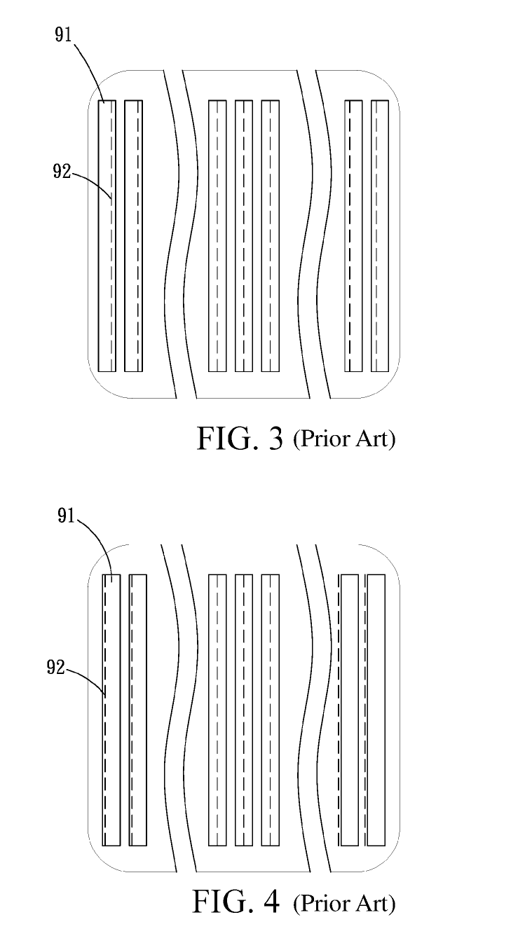

### DETAILED DESCRIPTION

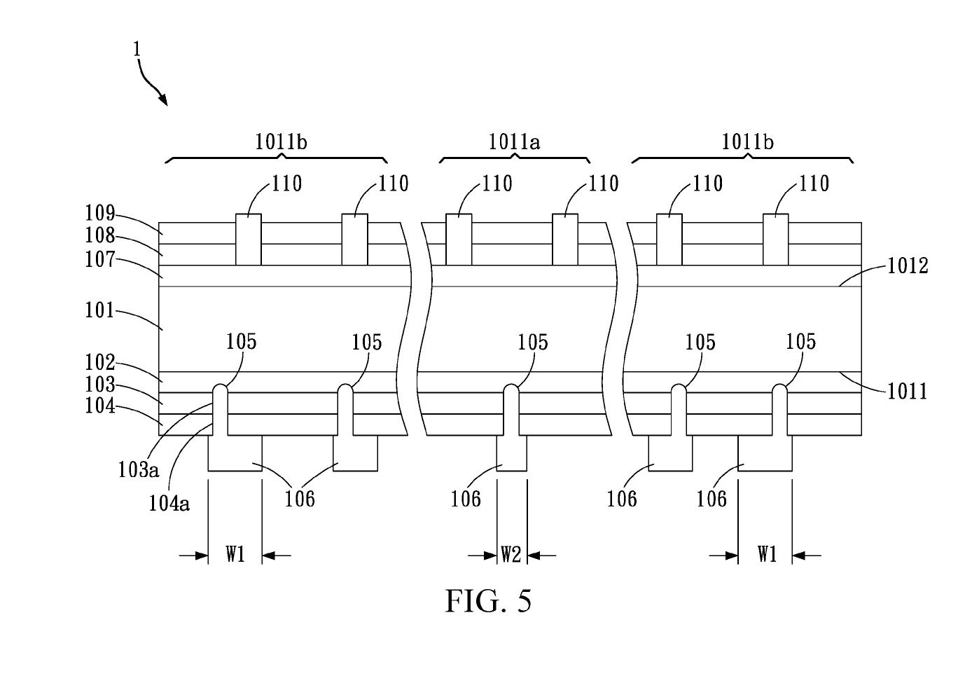

Please refer to FIG. 5, which is a schematic sectional diagram of a solar cell according to a first embodiment of the present invention and discloses a solar cell 1, including a semiconductor substrate 101, a first dopant layer 102, a first passivation layer 103, a first anti-reflection layer 104, a plurality of back surface fields 105, a plurality of back electrodes 106, a second dopant layer 107, a second passivation layer 108, a second anti-reflection layer 109, and a plurality of front surface electrodes 110.

The semiconductor substrate 101 is doped with a first-type dopant, and in this embodiment, the first-type dopant is a P-type dopant (for example, a group IIIA element, boron). The semiconductor substrate 101 has a first surface 1011 and a second surface 1012 opposite to the first surface 1011, the first surface 1011 has a central area 1011a and two side areas 1011b, and two side areas 1011b are respectively formed on two sides of the central area 1011a.

A first dopant layer 102 is formed on the first surface 1011 of the semiconductor substrate 101, the first dopant layer 102 is doped with a P-type dopant, a concentration of the P-type dopant of the first dopant layer 102 is greater than a concentration of the P-type dopant of the semiconductor substrate 101. The first passivation layer 103 is formed on the first dopant layer 102 and has a plurality of first through-holes 103a. The first anti-reflection layer 104 is formed on the first passivation layer 103 and has a plurality of second through-holes 104a individually corresponding to the plurality of the first through-holes 103a. The plurality of back surface fields 105 are formed at the first dopant layer 102 and individually correspond to the plurality of first through-holes 103a, and a concentration of the P-type dopant of the plurality of back surface fields 105 is greater than a concentration of the P-type dopant of the first dopant layer 102. The plurality of back electrodes 106 are arranged at intervals and are individually in electrical contact with the plurality of back surface fields 105 through the plurality of second through-holes 104a and the plurality of first through-holes 103a.

A second dopant layer 107 is formed on the second surface 1012 of the semiconductor substrate 101, the second dopant layer 107 is doped with a second-type dopant, and in this embodiment, the second-type dopant is a N-type dopant (for example, a group VA element). The second passivation layer 108 is formed on the second dopant layer 107 and has a plurality of third through-holes 108a. The second anti-reflection layer 109 is formed on the second passivation layer 108 and has a plurality of fourth through-holes 109a. The plurality of fourth through-holes 109a are individually corresponding to the plurality of the third through-holes 108a. The plurality of front surface electrodes 110 are individually in electrical contact with the second dopant layer 107 through the third through-holes 108a and the fourth through-holes 109a.

In this embodiment, widths W1 of the plurality of back electrodes 106 formed on the two side areas 1011b are greater than widths W2 of the plurality of back electrodes formed on the central area 1011a.

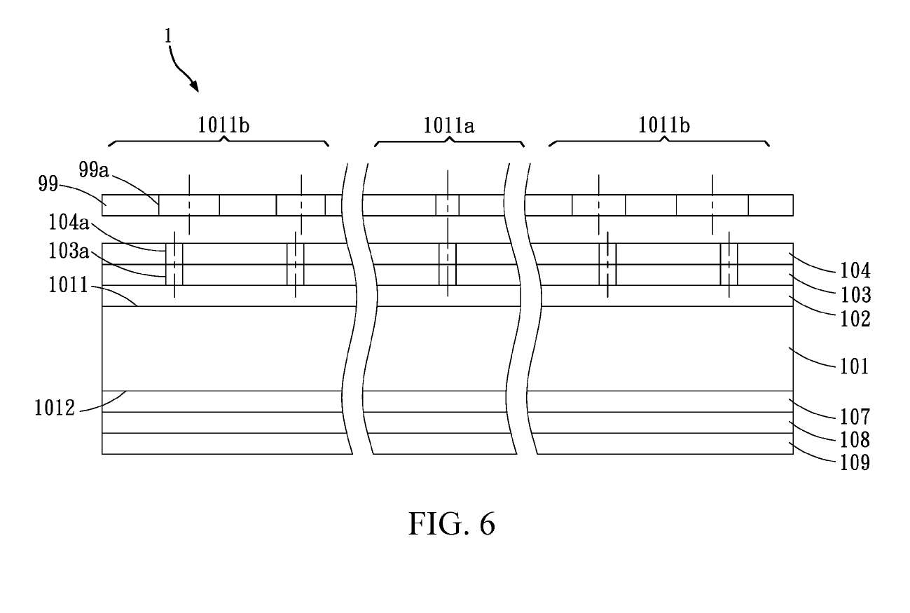

Please refer to FIG. 6, which is a schematic diagram of a screen printing process according to a first embodiment of the present invention, and in this embodiment, the first through-hole 103a and the second through-hole 104a are formed by means of a laser ablation process. After the plurality of first through-holes 103a and the plurality of second through-holes 104a are formed, a next process is filling the first through-holes 103a and the second through-holes 104a with conductive paste like aluminum paste via a screen printing. A screen plate 99 has a plurality of openings 99a, each opening 99a is aligned with each second through-hole 104a, and in this way, a squeegee may scrape the aluminum paste into the first through-holes 103a and the second through-holes 104a through the openings 99a. However, an inherent mechanical alignment error exists in aligning the openings 99a with the first through-holes 103a and the second through-holes 104a, and in addition, after the screen plate is used for many times, deformation may also occur because of material fatigue. Therefore, in practices, a process defect that often occurs is that after the screen printing is completed, some of the first through-holes 103a and the second through-holes 104a that are formed by means of laser ablation are not filled with the aluminum paste or partially filled with the aluminum paste. It could be found by means of further conclusion that a main reason why some of the first through-holes 103a and the second through-holes 104a that are formed by means of laser ablation are not filled with the aluminum paste is that translational misalignment or rotational misalignment occurs between the openings 99a of the screen plate 99 and the second through-holes 104a.

The foregoing translational misalignment and rotational misalignment particularly easily occur on two sides of the semiconductor substrate, and as a distance to the central area decreases, a possibility and a degree of occurrence of the translational misalignment and rotational misalignment are less obvious. In the first embodiment, widths W1 of the plurality of back electrodes 106 formed on the two side areas 1011b are greater than widths W2 of the plurality of back electrodes formed on the central area 1011a.

In this embodiment, a formation reason of the plurality of back surface fields 105 formed at the first dopant layer 102 is that after the first through-holes 103a and the second through-holes 104a are filled with the aluminum paste, a sintering process needs to be further carried so as to form the back electrodes 106. In the sintering process, because aluminum atoms would be dispersed into the first dopant layer 102, and both aluminum and boron belong to group IIIA elements, an area having a relatively high local P-type doping concentration (Local Back Surface Field) is formed at a contact place between the first dopant layer 102 and the back electrode 106, that is, in this embodiment, the back surface field 105 helps reduce a surface carrier composition effect between an aluminum back surface field and the semiconductor substrate and may also avoid warping and fragmentation phenomena caused the aluminum paste sintering.

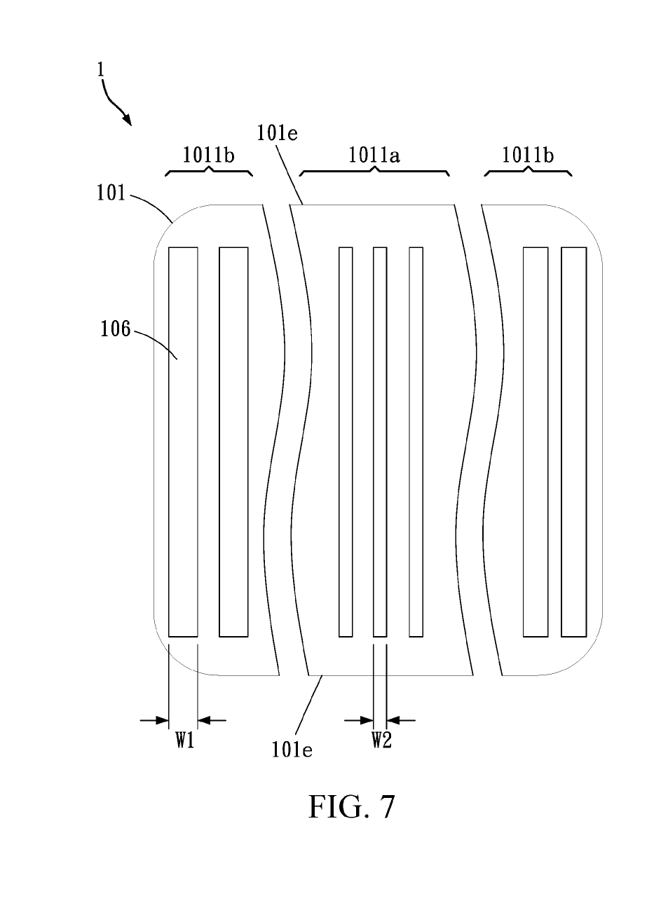

Please refer to FIG. 7, which is a top view of a back surface according to a first embodiment of the present invention. As shown in this drawing, in this embodiment, the so-called central area 1011a extends to edges 101e of the semiconductor substrate 101 along two sides parallel to a length direction of the back electrodes 106. The two side areas 1011b are respectively formed on two sides, of the central area 1011a, vertical to the length direction of the back electrodes 106, and a size of the central area 1011a is one tenth to one third of a size of the first surface 1011. Hence, if it is defined the size of the central area 1011a is one tenth of the size of the first surface 1011, the rest side areas 1011b occupy nine tenths of the size of the first surface 1011, that is, widths of 90% of the back electrodes 106 are increased, and widths of 10% of the back electrodes 106 are decreased. However, a total size of the back electrodes 106 after the width adjustment is still the same as that before the adjustment. Therefore, a power generation amount caused by incident light on the back surface would not be affected by the adjustment on the widths of the back electrodes 106. Hence, if it is defined the size of the central area 1011a is one third of the size of the first surface 1011, the rest side areas 1011b occupy two thirds of the size of the first surface 1011, that is, widths of two thirds of the back electrodes 106 are increased, and widths of one third of the back electrodes 106 are decreased. A total size of the back electrodes 106 after the width adjustment is still the same as that before the adjustment. Therefore, a power generation amount caused by incident light on the back surface would not be affected by the adjustment on the widths of the back electrodes 106.

Because different solar cells have different back electrode widths and have an equivalent width, the so-called increase or decrease in this embodiment is not an absolute value, but a relative concept. For example, for persons of ordinary skill in the art, if a back electrode width of a solar cell is usually X, when this embodiment is applied, the back electrode width of the central area is adjusted to be less than X and the back electrode widths of the side areas other than the central area are adjusted to be greater than X, and a total size of the back electrodes after the width adjustment is kept unchanged.

Please refer to FIG. 7 again. The present invention provides a second embodiment, and a main difference between the second embodiment and the first embodiment is that the size of the central area 1011a is one tenth to one fifth of the size of the first surface 1011. If it is defined the size of the central area 1011a is one fifth of the size of the first surface 1011, the rest side areas 1011b occupy four fifths of the size of the first surface 1011, that is, widths of four fifths of the back electrodes 106 are increased, and widths of one fifth of the back electrodes 106 are decreased. A total size of the back electrodes 106 after the width adjustment is still the same as that before the adjustment. Therefore, a power generation amount caused by incident light on the back surface would not be affected by the adjustment on the widths of the back electrodes 106.

In one manner of implementation, the widths W2 of the plurality of back electrodes 106 formed on the central area 1011a fall within a range of 30 microns to 100 microns. According to different types of solar cells, if the widths of the plurality of back electrodes 106 on the central area 1011a are adjusted to 30 microns, the widths of the back electrodes 106 on the central area 1011a are all 30 microns, and if the widths of the plurality of back electrodes 106 on the central area 1011a are adjusted to 100 microns, the widths of the back electrodes 106 on the central area 1011a are all 100 microns. In this way, the widths W1 of the plurality of back electrodes 106 on the side areas 1011b fall within a range of 40 microns to 250 microns.

For example, according to different types of solar cells, the widths of the plurality of back electrodes 106 on the central area 1011a may be adjusted to 30 microns, and the widths of the plurality of back electrodes 106 on the side areas 1011b may all be adjusted to 40 microns or above. Likewise, according to different types of solar cells, the widths W2 of all the back electrodes 106 on the central area 1011a may be adjusted to 100 microns, and the widths of the plurality of back electrodes 106 on the side areas 1011b may all be adjusted to 150 microns or above, for example, 250 microns.

In one manner of implementation, the widths W2 of the plurality of back electrodes 106 formed on the central area 1011a fall within a range of 30 microns to 150 microns. According to different types of solar cells, if the widths of the plurality of back electrodes 106 on the central area 1011a are adjusted to 30 microns, the widths of the back electrodes 106 on the central area 1011a are all 30 microns, and if the widths of the plurality of back electrodes 106 on the central area 1011a are adjusted to 150 microns, the widths of the back electrodes 106 on the central area 1011a are all 150 microns. In this way, the widths W1 of the plurality of back electrodes 106 on the side areas 1011b fall within a range of 40 microns to 250 microns. For example, according to different types of solar cells, the widths of the plurality of back electrodes 106 on the central area 1011a may be adjusted to 30 microns, and the widths of the plurality of back electrodes 106 on the side areas 1011b may all be adjusted to 40 microns or above. Likewise, according to different types of solar cells, the widths W2 of all the back electrodes 106 on the central area 1011a may be adjusted to 100 microns, and the widths of the plurality of back electrodes 106 on the side areas 1011b may all be adjusted to 150 microns or above, for example, 250 microns.

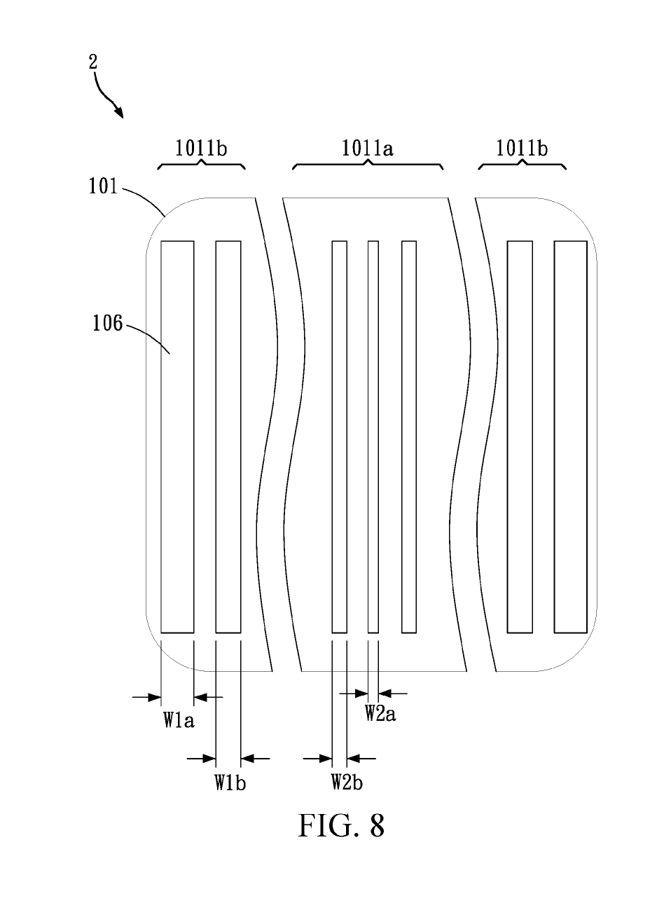

Please refer to FIG. 8, which is a top view of a back surface according to a third embodiment of the present invention. A main difference between this embodiment and the first embodiment and second embodiment is that the widths of the back electrodes 106 formed on the central area 1011a are not equivalent, and the widths of the back electrodes 106 formed on the side areas 1011a are also not equivalent. As shown in the drawing, the widths of the back electrodes 106 on the outermost sides of the side areas 1011b are W1a, and widths of the back electrodes 106 that are adjacent to the back electrodes 106 on the outermost sides and that are also formed on the side areas 1011b are W1b, where W1a is greater than W1b, and so on, the widths of the back electrodes 106 that are closer to the central area are smaller. Likewise, the widths of the back electrodes 106 in the middle-most of the central area 1011a are W2a, and widths of the back electrodes 106 that are adjacent to the back electrodes 106 in the middle-most and that are also formed on the central area 1011a are W2b, where W2a is greater than W2b, and by analogy, the widths of the back electrodes 106 that are more distant from the central area are greater. In an manner of implementation of this embodiment, the widths of the back electrodes 106 linearly progressively decrease from the widths W1a of the back electrodes 106 on the outermost sides of the side areas 1011b to the widths W2a of the back electrodes 106 in the middle-most of the central area 1011a, that is, a width difference between adjacent back electrodes 106 is a constant value.

Although in the foregoing embodiments, a total size of all the back electrodes 106 is kept the same before and after width adjustment, if a power generation amount of incident light on a back surface of a solar cell is not taken into consideration, the total size of all the back electrodes 106 after the width adjustment is allowed to be greater than or smaller than the total size of all the back electrodes 106 before the width adjustment.

What is claimed is:

1. A solar cell, comprising:
a semiconductor substrate, doped with a first-type dopant and having a first surface and a second surface opposite to the first surface, wherein the first surface has a central area and at least two side areas, the at least two side areas are respectively formed on two sides of the central area, a second dopant layer is formed on the second surface, and the second dopant layer is doped with a second-type dopant;
a first passivation layer, formed on the first surface and having a plurality of first through-holes;
a first anti-reflection layer, formed on the first passivation layer and having a plurality of second through-holes individually corresponding to the plurality of the first through-holes;
a plurality of back surface fields, formed at the first surface and individually corresponding to the plurality of first through-holes, wherein a concentration of the first-type dopant of the plurality of back surface fields is greater than a concentration of the first-type dopant of the first dopant layer;
a plurality of back electrodes, arranged at intervals and being individually in electrical contact with the plurality of back surface fields through the plurality of second through-holes and the plurality of first through-holes, wherein widths of the plurality of back electrodes on the at least two side areas are greater than widths of the plurality of back electrodes on the central area;
a second passivation layer, formed on the second dopant layer and having a plurality of third through-holes;
a second anti-reflection layer, formed on the second passivation layer and having a plurality of fourth through-holes individually corresponding to the plurality of third through-holes; and
a plurality of front surface electrodes, being individually in electrical contact with the second dopant layer through the third through-holes and the fourth through-holes.

2. The solar cell according to claim 1, wherein the central area extends to edges of the semiconductor substrate along two sides parallel to a length direction of the back electrodes, the at least two side areas are respectively formed on two sides, of the central area, vertical to the length direction of the back electrodes, and a size of the central area is one tenth to one third of a size of the first surface.

3. The solar cell according to claim 2, wherein the size of the central area is one tenth to one fifth of the size of the first surface.

4. The solar cell according to claim 3, wherein the widths of the plurality of back electrodes formed on the central area fall within a range of 30 microns to 100 microns.

5. The solar cell according to claim 4, wherein the widths of the plurality of back electrodes formed on the at least two side areas fall within a range of 40 microns to 250 microns.

6. The solar cell according to claim 2, wherein the widths of the plurality of back electrodes formed on the central area fall within a range of 30 microns to 150 microns.

7. The solar cell according to claim 6, wherein the width of the plurality of back electrodes formed on the at least two side areas fall within a range of 40 microns to 250 microns.

8. The solar cell according to claim 1, wherein a first dopant layer is formed on the first surface of the semiconductor substrate, the first dopant layer is doped with the first-type dopant, and a concentration of the first-type dopant of the first dopant layer is greater than a concentration of the first-type dopant of the semiconductor substrate.

9. The solar cell according to claim 6, wherein the widths of the plurality of back electrodes formed on the central area are identical to each other.

10. The solar cell according to claim 7, wherein the widths of the plurality of back electrodes formed on the at least two side areas are identical to each other.

11. The solar cell according to claim 1, wherein the first surface has a central line parallel to a length direction of the back electrodes, the plurality of back electrodes is arranged at intervals in a direction vertical to the central line, and widths of the plurality of back electrodes increase as a distance to the central line increases.
